(19) United States
(12) Patent Application Publication
(10) Pub. No.: US 2025/0347749 A1
(43) Pub. Date: Nov. 13, 2025

(54) BATTERY CONTROL APPARATUS AND METHOD

(71) Applicants: HYUNDAI MOTOR COMPANY, Seoul (KR); KIA CORPORATION, Seoul (KR)

(72) Inventors: Yo Han Baek, Hwaseong-si (KR); Yoo Hong Jang, Hwaseong-si (KR); Hyo Kyung Lee, Hwaseong-si (KR); Bo Hyun Lee, Hwaseong-si (KR)

(73) Assignees: HYUNDAI MOTOR COMPANY, Seoul (KR); KIA CORPORATION, Seoul (KR)

(21) Appl. No.: 18/924,482

(22) Filed: Oct. 23, 2024

(30) Foreign Application Priority Data
May 9, 2024 (KR) 10-2024-0061279

(51) Int. Cl. G01R 31/388; G01R 31/367; H01M 10/42; H01M 10/44

(52) U.S. Cl. CPC G01R 31/388; G01R 31/367; H01M 10/425; H01M 10/44; H01M 2010/4271

(57) ABSTRACT

A battery control apparatus and a method thereof are provided. The battery control apparatus includes a battery, a processor, and a memory. The processor identifies a diagnosis area for diagnosing an abnormal state of a battery cell included in the battery within a state of charge (SOC) area of the battery, performs, based on a specified current, at least one of charging, discharging, or any combination thereof of the battery in the diagnosis area to obtain battery data, obtains, using the battery data, cell data indicating a change in amount of charge for a voltage of the battery cell included in the battery, and compares at least one value of the cell data corresponding to the diagnosis area with at least one value of reference data corresponding to the diagnosis area to diagnose the battery cell.

### CROSS-REFERENCE TO RELATED APPLICATION

This application claims the benefit of and priority to Korean Patent Application No. 10-2024-0061279, filed on May 9, 2024, the entire contents of which are incorporated herein by reference.

### TECHNICAL FIELD

The present disclosure relates to a battery control apparatus and method, and more particularly, to technologies for diagnosing a battery.

### BACKGROUND

With the development of eco-friendly technology, research for diagnosing a battery loaded into an eco-friendly vehicle has been in progress. For example, the eco-friendly vehicle may include a hybrid electric vehicle (HEV), an electric vehicle (EV), a plug-in hybrid electric vehicle (PHEV), and/or a fuel cell electric vehicle (FCEV). If a defect of the battery occurs in a relatively low state of charge (SOC) area of the battery, the defect of the battery may fail to be identified in another SOC area. If the battery is discharged by the driving of the vehicle upon battery diagnosis, because it is difficult to discharge the battery to the relatively low SOC area of the battery, the defect of the battery may fail to be identified.

The statements in this Background section merely provide background information related to the present disclosure and may not constitute prior art.

### SUMMARY

The present disclosure has been made to solve the above-mentioned problems occurring in the prior art while advantages achieved by the prior art are maintained intact.

An aspect of the present disclosure provides a battery control apparatus and method for diagnosing a state of a battery.

Another aspect of the present disclosure provides a battery control apparatus and method for setting a diagnosis area with a high frequency of use in an SOC area of a battery.

Another aspect of the present disclosure provides a battery control apparatus and method for providing information on a risk of a battery diagnosed as being in an abnormal state.

The technical problems to be solved by the present disclosure are not limited to the aforementioned problems, and any other technical problems not mentioned herein should be clearly understood from the following description by those having ordinary skill in the art to which the present disclosure pertains.

According to an embodiment of the present disclosure, a battery control apparatus may include a battery, a processor, and a memory configured to store one or more instructions executable by the processor. The processor may be configured to: identify a diagnosis area for diagnosing an abnormal state of a battery cell included in the battery within a state of charge (SOC) area of the battery; perform at least one of charging, discharging, or any combination thereof of the battery in the diagnosis area to obtain battery data, based on a specified current; obtain cell data indicating a change in amount of charge for a voltage of the battery cell included in the battery, using the battery data; and compare at least one value of the cell data corresponding to the diagnosis area with at least one value of reference data corresponding to the diagnosis area to diagnose the battery cell.

In an embodiment, the diagnosis area may include a first sub-diagnosis area and a second sub-diagnosis area. The second sub-diagnosis area may include a SOC value smaller than at least one SOC value included in the first sub-diagnosis area. In an embodiment, the processor may be configured to diagnose a state of the battery cell as the abnormal state when the at least one value of the cell data corresponding to at least one of the first sub-diagnosis area, the second sub-diagnosis area, or any combination thereof deviates from a diagnostic range including the at least one value of the reference data corresponding to at least one of the first sub-diagnosis area, the second sub-diagnosis area, or any combination thereof.

In an embodiment, the processor may be configured to compare a minimum value of the cell data corresponding to the first sub-diagnosis area of the diagnosis area with a minimum value of the reference data corresponding to the first sub-diagnosis area and diagnose the state of the battery cell as the abnormal state when the minimum value of the cell data is less than the minimum value of the reference data by a specified value.

In an embodiment, the processor may be configured to compare a maximum value of the cell data corresponding to the second sub-diagnosis area of the diagnosis area with a maximum value of the reference data corresponding to the second sub-diagnosis area and diagnose the state of the battery cell as the abnormal state when the maximum value of the cell data is greater than the maximum value of the reference data by a specified value.

In an embodiment, the processor may be configured to determine a risk of the battery cell diagnosed as being in the abnormal state. The risk of the battery cell diagnosed as being in the abnormal state based on the first sub-diagnosis area may include a value smaller than another risk of the battery cell diagnosed as being in the abnormal state based on the second sub-diagnosis area.

In an embodiment, the diagnosis area may have a higher frequency of use than another area differentiating from the diagnosis area in the SOC area of the battery.

In an embodiment, the processor may be configured to compare the at least one value of the cell data corresponding to the diagnosis area with the at least one value of the reference data corresponding to the diagnosis area to diagnose the abnormal state of the battery cell. The abnormal state may occur in another area differentiating from the diagnosis area in the SOC area of the battery.

In an embodiment, the processor may be configured to identify an SOC of the battery and perform at least one of charging, discharging, or any combination thereof of the battery, based on the specified current, to obtain the battery data for at least a portion of the diagnosis area, based on identifying the SOC of the battery (e.g., based on the identified SOC of the battery).

In an embodiment, the processor may be configured to determine the at least a portion of the diagnosis area. The at least a portion of the diagnosis area is adjacent to the SOC of the battery, based on identifying the SOC of the battery (e.g., based on the identified SOC of the battery).

In an embodiment, the processor may be configured to obtain the battery data, based on the specified current less than a threshold current.

According to another embodiment of the present disclosure, a battery control method may include: identifying a diagnosis area for diagnosing an abnormal state of a battery cell included in a battery within a state of charge (SOC) area of a battery; performing at least one of charging, discharging, or any combination thereof of the battery in the diagnosis area to obtain battery data, based on a specified current; obtaining the battery data; obtaining cell data indicating a change in amount of charge for a voltage of the battery cell included in the battery, using the battery data; comparing at least one value of the cell data corresponding to the diagnosis area with at least one value of reference data corresponding to the diagnosis area to diagnose the battery cell; and diagnosing the battery cell.

In an embodiment, the diagnosis area may include a first sub-diagnosis area and a second sub-diagnosis area. The second sub-diagnosis area may include a SOC value smaller than at least one SOC value included in the first sub-diagnosis area. Diagnosing the battery cell may include diagnosing a state of the battery cell as the abnormal state when the at least one value of the cell data corresponding to at least one of the first sub-diagnosis area, the second sub-diagnosis area, or any combination thereof deviates from a diagnostic range including the at least one value of the reference data corresponding to at least one of the first sub-diagnosis area, the second sub-diagnosis area, or any combination thereof.

In an embodiment, diagnosing the battery cell may include: comparing a minimum value of the cell data corresponding to the first sub-diagnosis area of the diagnosis area with a minimum value of the reference data corresponding to the first sub-diagnosis area; and diagnosing the state of the battery cell as the abnormal state when the minimum value of the cell data is less than the minimum value of the reference data by a specified value.

In an embodiment, diagnosing the battery cell may include: comparing a maximum value of the cell data corresponding to the second sub-diagnosis area of the diagnosis area with a maximum value of the reference data corresponding to the second sub-diagnosis area; and diagnosing the state of the battery cell as the abnormal state when the maximum value of the cell data is greater than the maximum value of the reference data by a specified value.

In an embodiment, diagnosing the battery cell may include determining a risk of the battery cell diagnosed as being in the abnormal state. The risk of the battery cell diagnosed as being in the abnormal state based on the first sub-diagnosis area may include a value smaller than another risk of the battery cell diagnosed as being in the abnormal state based on the second sub-diagnosis area.

In an embodiment, the diagnosis area may have a higher frequency of use than another area differentiating from the diagnosis area in the SOC area of the battery.

In an embodiment, diagnosing the battery cell may include comparing the at least one value of the cell data corresponding to the diagnosis area with the at least one value of the reference data corresponding to the diagnosis area to diagnose the abnormal state of the battery cell, the abnormal state occurring in another area differentiating from the diagnosis area in the SOC area of the battery.

In an embodiment, obtaining the battery data may include: identifying an SOC of the battery; and performing at least one of charging, discharging, or any combination thereof of the battery, based on the specified current, to obtain the battery data for at least a portion of the diagnosis area, based on identifying the SOC of the battery (e.g., based on the identified SOC of the battery).

In an embodiment, identifying the SOC of the battery may include determining the at least a portion of the diagnosis area. The at least a portion of the diagnosis area is adjacent to the SOC of the battery, based on identifying the SOC of the battery (e.g., based on the identified SOC of the battery).

In an embodiment, obtaining the battery data may include obtaining the battery data, based on the specified current less than a threshold current.

### BRIEF DESCRIPTION OF THE DRAWINGS

The above and other objects, features and advantages of the present disclosure should be more apparent from the following detailed description taken in conjunction with the accompanying drawings:

FIG. 1 illustrates an example of a block diagram associated with a battery control apparatus according to an embodiment of the present disclosure;

FIG. 2 illustrates an example of cell data obtained using battery data in a battery control apparatus according to an embodiment of the present disclosure;

FIG. 3 illustrates an example of a diagnosis area set to diagnose a battery in a battery control apparatus according to an embodiment of the present disclosure;

FIG. 4 illustrates an example for describing an operation of comparing cell data with reference data in a battery control apparatus according to an embodiment of the present disclosure;

FIG. 5 illustrates an example of a flowchart illustrating an operation of a battery control apparatus according to an embodiment of the present disclosure;

FIG. 6 illustrates an example of a flowchart illustrating an operation of obtaining battery data in a battery control apparatus according to an embodiment of the present disclosure;

FIG. 7 illustrates an example of a flowchart illustrating a preprocessing operation for comparing cell data with reference data in a battery control apparatus according to an embodiment of the present disclosure;

FIG. 8 illustrates an example of a flowchart illustrating an operation of diagnosing a battery cell using cell data in a battery control apparatus according to an embodiment of the present disclosure;

FIG. 9 illustrates an example of an operation of determining a risk of a diagnosed battery cell in a battery control apparatus according to an embodiment of the present disclosure;

FIG. 10 illustrates an example of a flowchart illustrating an operation of a battery control apparatus according to an embodiment of the present disclosure; and

FIG. 11 illustrates a computing system associated with a battery control apparatus or a battery control method according to an embodiment of the present disclosure.

The drawings described herein are for illustration purposes only and are not intended to limit the scope of the present disclosure in any way.

### DETAILED DESCRIPTION

Hereinafter, some embodiments of the present disclosure are described in detail with reference to the drawings. In adding the reference numerals to the components of each drawing, it should be noted that the identical component is designated by the identical numerals even when they are displayed on other drawings. In addition, a detailed description of well-known features or functions has been ruled out in order not to unnecessarily obscure the gist of the present disclosure.

In describing components of embodiments of the present disclosure, the terms first, second, A, B, (a), (b), and the like may be used herein. These terms are only used to distinguish one component from another component, but do not limit the corresponding components irrespective of the order or priority of the corresponding components. Furthermore, unless otherwise defined, all terms including technical and scientific terms used herein have the same meaning as being generally understood by those having ordinary skill in the art to which the present disclosure pertains. Such terms as those defined in a generally used dictionary are to be interpreted as having meanings equal to the contextual meanings in the relevant field of art and are not to be interpreted as having ideal or excessively formal meanings unless clearly defined as having such in the present application.

The term “module” used in various embodiments of the present disclosure may include a unit implemented with hardware, software, or firmware, and may be interchangeably used with terms, for example, “logic,” “logic block,” “part,” or “circuitry”. A module may be an integral part, or a minimum unit or portion thereof, adapted to perform one or more functions. In an embodiment, the module may be implemented in the form of an application-specific integrated circuit (ASIC). According to various embodiments, operations performed by the module, the program, or another component may be carried out sequentially, in parallel, or repeatedly, or one or more of the operations may be executed in a different order or omitted, or one or more other operations may be added.

Various embodiments of the present disclosure may be implemented as software (e.g., a program) including one or more instructions stored in a storage medium (e.g., an internal memory or an external memory) readable by a machine (e.g., a battery control apparatus 100). For example, a processor (e.g., a processor 110) of the device (e.g., the battery control apparatus 100) may read and execute at least one of the stored one or more instructions from the storage medium. This allows the machine to be operated to perform at least one function according to the at least one instruction. The one or more instructions may include a code generated by a complier or a code executable by an interpreter. The machine-readable storage medium may be provided in the form of a non-transitory storage medium. The term “non-transitory” simply means that the storage medium is a tangible device and does not include a signal (e.g., an electromagnetic wave), but this term does not differentiate between where data is semipermanently stored in the storage medium and where data is temporarily stored in the storage medium.

When a component, controller, processor, unit, module, device, element, apparatus, or the like of the present disclosure is described as having a purpose or performing an operation, function, or the like, the component, controller, processor, unit, module, device, element, apparatus, or the like should be considered herein as being “configured to” meet that purpose or to perform that operation or function.

In the present disclosure, each of phrases such as “A or B”, “at least one of A and B”, “at least one of A or B”, “A, B or C”, “at least one of A, B and C”, “at least one of A, B or C” and “at least one of A, B, or C, or a combination thereof” may include any one or all possible combinations of the items listed together in the corresponding one of the phrases.

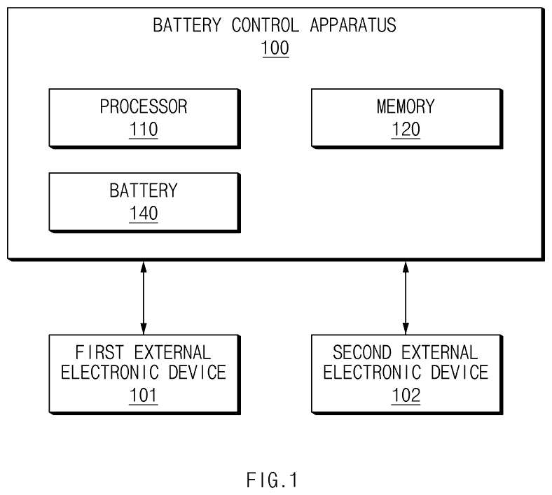

Hereinafter, embodiments of the present disclosure are described in detail with reference to FIGS. 1 to 11.

FIG. 1 illustrates an example of a block diagram associated with a battery control apparatus according to an embodiment of the present disclosure.

Referring to FIG. 1, a battery control apparatus 100 according to an embodiment of the present disclosure may be implemented inside or outside a vehicle, and some of components included in the battery control apparatus 100 may be implemented inside or outside the vehicle. In this case, the battery control apparatus 100 may be integrally configured with control units in the vehicle or may be implemented as a separate device to be connected with the control units of the vehicle by a separate connection means. For example, the battery control apparatus 100 may further include components which are not shown in FIG. 1.

The battery control apparatus 100 according to an embodiment may include at least one of a processor 110, a memory 120, or a battery 140. The processor 110, the memory 120, and the battery 140 may be electronically or operably coupled with each other by an electronical component including a communication bus. Hereinafter, that pieces of hardware are operably coupled with each other may mean that a direct connection or an indirect connection between the pieces of hardware is established in a wired or wireless manner, such that second hardware is controlled by first hardware among the pieces of hardware. They are illustrated based on the different blocks, but an embodiment is not limited thereto. Some of the pieces of hardware of FIG. 1 (e.g., at least some of the processor 110, the memory 120, and a communication circuit (not shown)) may be included in a single integrated circuit such as a system on a chip (SOC).

The processor 110 of the battery control apparatus 100 according to an embodiment may include a hardware component for processing data based on one or more instructions. The hardware component for processing the data may include, for example, an arithmetic and logic unit (ALU), a floating point unit (FPU), a field programmable gate array (FPGA), a central processing unit (CPU), a micro controlling unit (MCU), and/or an application processor (AP). The number of the processors 110 may be one or more in number. For example, the processor 110 may have a structure of a multi-core processor including a dual core, a quad core, a hexa core, or an octa core.

The memory 120 of the battery control apparatus 100 may include a hardware component for storing data and/or instructions input and/or output from the processor 110. The memory 120 may include, for example, a volatile memory, such as a random-access memory (RAM), and/or a non-volatile memory, such as a read-only memory (ROM). For example, the volatile memory may include at least one of a dynamic RAM (DRAM), a static RAM (SRAM), a cache RAM, or a pseudo SRAM (PSRAM). For example, the non-volatile memory may include at least one of a programmable ROM (PROM), an erasable PROM (EPROM), an electrically erasable PROM (EEPROM), a flash memory, a hard disk, a compact disc, or an embedded multi-media card (eMMC). The processor 110 and/or the memory 120 may be associated with a battery management system (BMS) for controlling and/or managing the battery 140.

According to an embodiment, the battery 140 of the battery control apparatus 100 may include a battery cell, a battery module, or a battery pack. For example, the battery 140 may be composed of one or more unit cells. The battery 140 may include a capacitor or a secondary battery, which stores power depending on charging. For example, the battery 140 may include any one of a lithium (Li)-ion battery, a Li-ion polymer battery, a lead-acid battery, a nickel-cadmium (NiCd) battery, a nickel-metal hydride (NiMH) battery, or a lithium-iron phosphate (LFP) battery. However, it is not limited thereto.

For example, the battery 140 may include a controller and/or a sensor. For example, the controller included in the battery 140 may include a battery management unit (BMU) and/or a cell monitoring unit (CMU).

For example, the sensor included in the battery 140 may transmit sensor data based on a voltage and/or current of the battery 140 to the processor 110. Receiving the sensor data based on the voltage and/or current of the battery 140, the processor 110 may measure the voltage and/or current of the battery 140.

In an embodiment, a first external electronic device 101 may include an electronic device for charging (or discharging) the battery 140. The first external electronic device 101 may include a charger, a discharger, a slow charger, hardware (e.g., a heater) for discharging the battery 140, and/or a vehicle-to-load (V2L). However, it is not limited thereto.

In an embodiment, a second external electronic device 102 may include an electronic device for diagnosing the battery 140. The second external electronic device 102 may include diagnostic equipment (e.g., global diagnostic system (GDS)), a control device, and/or a server (e.g., a cloud server). In an embodiment, the first external electronic device 101 and the second external electronic device 102 may be included in the battery control apparatus 100.

The battery control apparatus 100 according to an embodiment may diagnose the battery 140. For example, the battery control device 100 may set a diagnosis area in an SOC area of the battery 140. The battery control apparatus 100 may determine a defect in the battery 140, which occurs in another area differentiating from the diagnosis area in the SOC area, using the battery data included in the diagnosis area (e.g., using the battery data corresponding to or obtained from the diagnosis area).

The battery control apparatus 100 may identify a diagnosis area for diagnosing an abnormal state of a battery cell included in the battery 140 in the SOC area of the battery 140. For example, the diagnosis area may have a higher frequency of use than the other area differentiating from the diagnosis area in the SOC area of the battery 140. For example, the meaning that the frequency of use of the diagnosis area is high may include the meaning that a probability that the SOC of the battery 140 will be included in the diagnosis area is higher than a probability that the SOC will be included in the other area. In other words, the case in which the battery control apparatus 100 charges or discharges the battery 140 in the diagnosis area may be relatively greater than the case in which the battery control apparatus 100 charges or discharges the battery 140 in the other area.

For example, the diagnosis area may include one or more sub-diagnosis areas. For example, the diagnosis area may include a first sub-diagnosis area and a second sub-diagnosis area including a value smaller than at least one value included in the first sub-diagnosis area.

For example, the diagnosis area may be identified based on data set based on a usage history of the battery 140. For example, the battery control apparatus 100 may set a diagnosis area with a relatively high frequency of use, using the usage history of the battery 140. However, it is not limited thereto.

The battery control apparatus 100 may perform at least one of charging or discharging, or any combination thereof of the battery 140 in the diagnosis area to obtain battery data, based on a specified current.

For example, the battery control apparatus 100 may obtain battery data, based on the specified current which is less than a threshold current (e.g., 0.05 C).

For example, the battery control apparatus 100 may identify an SOC of the battery 140. For example, the battery control apparatus 100 may perform at least one of charging or discharging, or any combination thereof of the battery 140, based on the specified current, to obtain battery data for at least a portion of the diagnosis area, based on identifying the SOC of the battery 140.

For example, the battery control apparatus 100 may obtain the battery data for the at least a portion of the diagnosis area included in a charging range of the battery 140 (or a discharging range of the battery 140), based on performing the at least one of the charging or the discharging, or the any combination thereof of the battery 140.

For example, the battery data may include data for a voltage and/or current of the battery 140.

In an embodiment, the battery control apparatus 100 may determine whether to charge (or discharge) the battery 140, based on identifying the SOC of the battery 140.

For example, the battery control apparatus 100 may determine at least a portion of the diagnosis area, which is adjacent to the SOC of the battery 140, based on identifying the SOC of the battery 140. For example, the at least a portion of the diagnostic area may include the first sub-diagnosis area and/or the second sub-diagnosis area.

For example, if the SOC of the battery 140 is adjacent to the first sub-diagnosis area between the first sub-diagnosis area and the second sub-diagnosis area, the battery control apparatus 100 may obtain battery data for the first sub-diagnosis area. However, it is not limited thereto. The battery control apparatus 100 may battery data for the entire diagnosis area.

The battery control apparatus 100 may obtain cell data indicating a change in amount of charge for the voltage of the battery cell included in the battery 140, using the battery data.

The battery control apparatus 100 may compare at least one value of the cell data included in the diagnosis area (e.g., at least one value of the cell data corresponding to the diagnosis area or at least one value of the cell data obtained from the diagnosis area) with at least one value of reference data included in the diagnosis area (e.g., at least one value of the reference data corresponding to the diagnosis area or at least one value of the reference data obtained from the diagnosis area) to diagnose the battery cell. When data (e.g., the cell data or the reference data) is described as included in an area (e.g., the diagnosis area) it may mean that the data may correspond to or obtained from the area or at least a portion of the area (e.g., a sub-area within the area or a point within the area).

For example, the reference data may indicate an average value for cell data of each of a plurality of battery cells included in the battery 140.

For example, the reference data may indicate cell data for a battery cell which is in a normal state. However, it is not limited thereto.

If the at least one value of the cell data included in at least one of the first sub-diagnosis area, the second sub-diagnosis area, or any combination thereof (e.g., at least one value of the cell data corresponding to at least one of the first sub-diagnosis area, the second sub-diagnosis area, or any combination thereof) deviates from a diagnostic range including the at least one value of the reference data included in at least one of the first sub-diagnosis area, the second sub-diagnosis area, or any combination thereof (a diagnostic range including the at least one value of the reference data corresponding to at least one of the first sub-diagnosis area, the second sub-diagnosis area, or any combination thereof), the battery control apparatus 100 may diagnose the state of the battery cell as an abnormal state.

For example, if the cell data is cell data corresponding to the first sub-diagnosis area, the at least one value of the cell data may indicate a minimum value. For example, if the cell data is cell data corresponding to the second sub-diagnosis area, the at least one value of the cell data may indicate a maximum value. However, it is not limited thereto.

The battery control apparatus 100 may compare the minimum value of the cell data included in the first sub-diagnosis area of the diagnosis area (e.g., the minimum value of the cell data for the first sub-diagnosis area of the diagnosis area) with the minimum value of the reference data included in the first sub-diagnosis area (e.g., the minimum value of the reference data corresponding to the first sub-diagnosis area).

For example, if the minimum value of the cell data is less than the minimum value of the reference data by a specified value (e.g., 3 sigma), the battery control apparatus 100 may diagnose the state of the battery cell as the abnormal state. For example, the specified value may indicate a standard deviation.

The battery control apparatus 100 may compare the maximum value of the cell data included in the second sub-diagnosis area of the diagnosis area (e.g., maximum value of the cell data corresponding to the second sub-diagnosis area of the diagnosis area) with the maximum value of the reference data included in the second sub-diagnosis area (e.g., the maximum value of the reference data corresponding to the second sub-diagnosis area).

For example, if the maximum value of the cell data is greater than the maximum value of the reference data by the specified value, the battery control apparatus 100 may diagnose the state of the battery cell as the abnormal state.

The battery control apparatus 100 according to an embodiment may determine a risk of the battery cell diagnosed as being in the abnormal state.

For example, the risk of the battery cell diagnosed as being in the abnormal state based on the first sub-diagnosis area may include a value smaller than another risk of the battery cell diagnosed as being in the abnormal state based on the second sub-diagnosis area.

In other words, the battery cell diagnosed using the cell data corresponding to the first sub-diagnosis area may have a risk lower than the battery cell diagnosed using the cell data corresponding to the second sub-diagnosis area. However, it is not limited thereto.

As described above, the battery control apparatus 100 according to an embodiment may diagnose whether the battery cell is abnormal. For example, the battery control apparatus 100 may identify a phenomenon in which voltage suddenly drops, which occurs in a specified SOC area (e.g., a low-voltage area). For example, the battery control apparatus 100 may identify the battery cell in which the voltage drop phenomenon occurs in the specified area, using the battery data corresponding to the diagnosis area differentiating from the specified SOC area. The battery control apparatus 100 may identify the battery cell in which the voltage drop phenomenon occurs using the battery data corresponding to the diagnosis area, without the necessity of discharging the battery 140 to the specified SOC area.

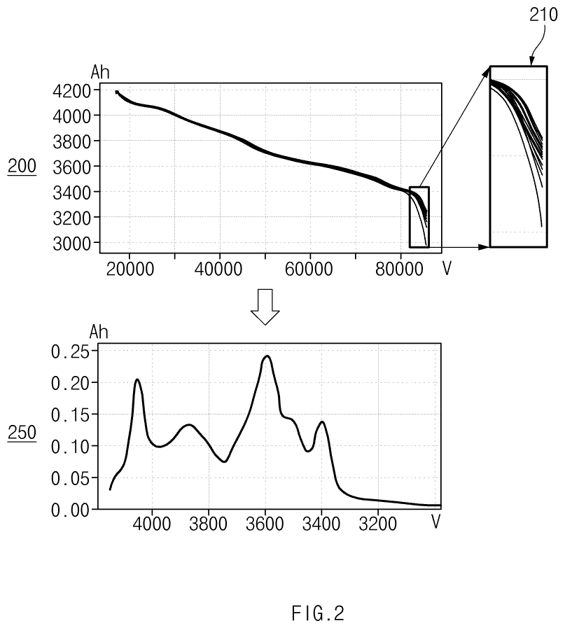

FIG. 2 illustrates an example of cell data obtained using battery data in a battery control apparatus according to an embodiment of the present disclosure. A battery control apparatus of FIG. 2 may be referred to a battery control apparatus 100 of FIG. 1.

Referring to FIG. 2, the battery control apparatus according to an embodiment may obtain battery data 200 for at least a portion of a diagnosis area. The battery data 200 may include data for a voltage and a current of a battery. The battery data 200 may include data indicating a voltage drop phenomenon 210 which occurs in a specified area (e.g., a low-voltage area).

The battery control apparatus may obtain cell data 250 indicating an amount of change in current (or a change in amount of charge for voltage) per unit voltage, using the battery data 200. For example, the battery control apparatus may log the battery data 200 to obtain the cell data 250.

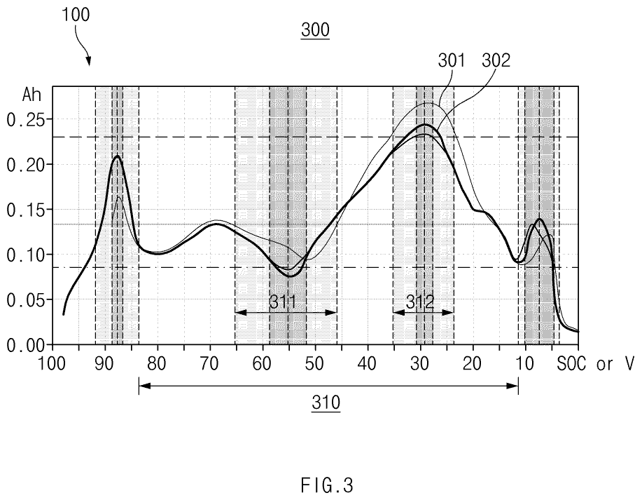

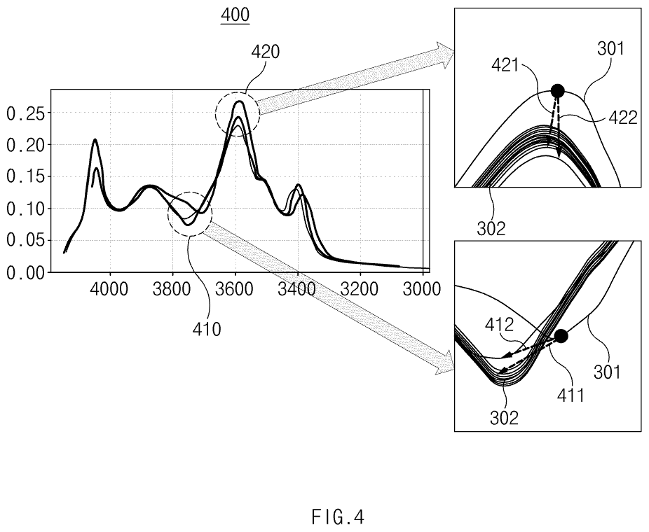

FIG. 3 illustrates an example of a diagnosis area set to diagnose a battery in a battery control apparatus according to an embodiment of the present disclosure. FIG. 4 illustrates an example for describing an operation of comparing cell data with reference data in a battery control apparatus according to an embodiment of the present disclosure. A battery control apparatus 100 of FIG. 3 or 4 may be referred to a battery control apparatus 100 of FIG. 1.

Referring to FIG. 3, a graph 300 including a graph 302 illustrating cell data (e.g., cell data 250 of FIG. 2) and a graph 301 illustrating reference data for diagnosing whether a battery cell is abnormal is illustrated.

The battery control apparatus 100 may identify a diagnosis area 310 (e.g., 25% to 65%) for diagnosing an abnormal state of a battery cell included in a battery 140 in an SOC area of the battery 140. For example, the diagnosis area 310 may have a higher frequency of use than another area differentiating from the diagnosis area 310 in the SOC area of the battery 140.

For example, the diagnosis area 310 may be identified based on data set based on a usage history of the battery 140. For example, the battery control apparatus 100 may set a diagnosis area with a relatively high frequency of use, using the usage history of the battery 140.

For example, the diagnosis area 310 may include one or more sub-diagnosis areas. For example, the diagnosis area 310 may include a first sub-diagnosis area 311 (e.g., 45% to 65%) and a second sub-diagnosis area 312 (e.g., 25% to 35%) including a value smaller than at least one value included in the first sub-diagnosis area 311. The first sub-diagnosis area 311 may include an area corresponding to an SOC higher than the second sub-diagnosis area 312. For example, the first sub-diagnosis area 311 and/or the second sub-diagnosis area 312 may include an inflection point of the graph 310 and/or an inflection point of the graph 302. The inflection point may include a position at which the direction changes in the curve of the graph 301 and/or the curve of the graph 302. The inflection point may include a minimum value and/or a maximum value of the graph 301 in the diagnosis area 310. The inflection point may include a minimum value and/or a maximum value of the graph 302 in the diagnosis area 310.

Referring to FIG. 4, in an example 400, the battery control apparatus 100 may compare the graph 301 with the graph 302 to diagnose an abnormal state of a cell battery associated with the graph 301.

For example, in a first inflection point area 410 included in the first sub-diagnosis area 311, the battery control apparatus 100 may compare the graph 301 with the graph 302.

For example, the battery control apparatus 100 may identify a diagnostic distance (or a diagnostic length) 412 between at least one value of the graph 301 and at least one value of the graph 302 in the first inflection point area 410. For example, if the diagnostic distance 412 is greater than a specified distance 411, the battery control apparatus 100 may diagnose a state of a battery cell, which corresponds to the graph 302, as an abnormal state.

For example, if the minimum value of the graph 302 included in the first inflection point area 410 deviates from a diagnostic range (e.g., −3 sigma to +3 sigma) including the minimum value of the graph 301, the battery control apparatus 100 may diagnose the state of the battery cell, which corresponds to the graph 302, as the abnormal state.

For example, when using cell data for each of the plurality of battery cells, the battery control apparatus 100 may diagnose a battery cell, in which the x-vector based on 2 dimensions (e.g., a coordinate system based on the x-axis and the y-axis) has a relatively large value and the y-vector has a relative small value, among the plurality of battery cells as an abnormal battery cell, in the first inflection point area 410. The x-vector and the y-vector may be identified using an inflection point of each of a plurality of graphs illustrating cell data for each of the plurality of battery cells and an inflection point of the graph 301 in the first inflection point area 410.

For example, if the minimum value of the graph 302 included in the first inflection point area 410 is less than the minimum value of the graph 301 by a specified value (e.g., −3 sigma), the battery control apparatus 100 may diagnose the state of the battery cell, which corresponds to the graph 302, as the abnormal state.

For example, in a second inflection point area 420 included in the second sub-diagnosis area 312, the battery control apparatus 100 may compare the graph 301 with the graph 302.

For example, the battery control apparatus 100 may identify a diagnostic distance (or a diagnostic length) 422 between at least one value of the graph 301 and at least one value of the graph 302 in the second inflection point area 420. For example, if the diagnostic distance 422 is greater than a specified distance 421, the battery control apparatus 100 may diagnose a state of a battery cell, which corresponds to the graph 302, as the abnormal state.

For example, if the maximum value of the graph 302 included in the second inflection point area 420 deviates from a diagnostic range (e.g., −3 sigma to +3 sigma) including the maximum value of the graph 301, the battery control apparatus 100 may diagnose the state of the battery cell, which corresponds to the graph 302, as the abnormal state.

For example, if the maximum value of the graph 302 included in the second inflection point area 420 is greater than the maximum value of the graph 301 by a specified value (e.g., +3 sigma), the battery control apparatus 100 may diagnose the state of the battery cell, which corresponds to the graph 302, as the abnormal state.

For example, if using cell data for each of the plurality of battery cells, the battery control apparatus 100 may diagnose a battery cell, in which the y-vector based on 2 dimensions has a relatively small value, among the plurality of battery cells, as an abnormal battery cell in the second inflection point area 420. The x-vector and the y-vector may be identified using an inflection point of each of a plurality of graphs illustrating cell data for each of the plurality of battery cells and an inflection point of the graph 301 in the second inflection point area 420. However, it is not limited thereto.

For example, the battery control apparatus 100 may determine a state of a battery cell which is not diagnosed as being in the abnormal state as a normal state. However, it is not limited thereto.

As described above, the battery control apparatus 100 may compare the at least one value included in the graph 301 with the at least one value included in the graph 302 to diagnose the state of the battery cell. For example, the battery control apparatus 100 may diagnose the state of the battery cell using a length between the at least one value included in the graph 301 and the at least one value included in the graph 302. For example, the battery control apparatus 100 may diagnose the state of the battery cell based on a vector value (e.g., the x-vector or the y-vector) between the at least one value included in the graph 301 and the at least one value included in the graph 302.

In one embodiment, when determining whether the battery cell is abnormal in the first inflection point area 410, the battery control apparatus 100 may diagnose an abnormal state of the battery cell, using a second specified value (e.g., −3 sigma) between a first specified value (e.g., +3 sigma) and the second specified value. In another embodiment, when determining whether the battery cell is abnormal in the second inflection point area 420, the battery control apparatus 100 may diagnose an abnormal state of the battery cell, using the first specified value (e.g., +3 sigma) between the first specified value and the second specified value (e.g., −3 sigma). However, it is not limited thereto.

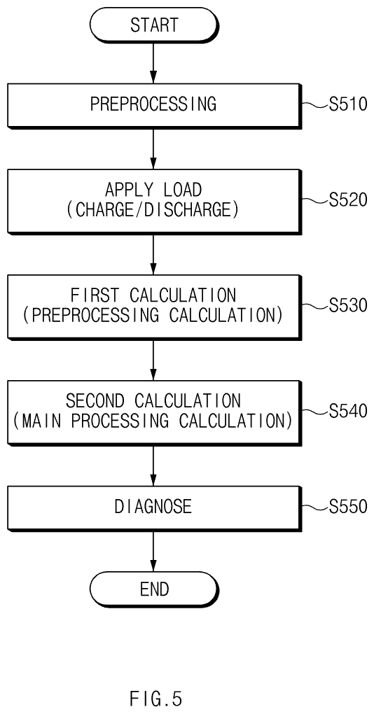

FIG. 5 illustrates an example of a flowchart illustrating an operation of a battery control apparatus according to an embodiment of the present disclosure. Hereinafter, it is assumed that a battery control apparatus 100 of FIG. 1 performs a process of FIG. 5. Furthermore, in a description of FIG. 5, an operation described as being performed by a battery control apparatus may be understood as being controlled by a processor 110 of the battery control apparatus 100. The respective operations of FIG. 5 may be sequentially performed, but are not necessarily sequentially performed. For example, an order of the respective operations may be changed, and at least two operations may be performed in parallel.

Referring to FIG. 5, in an operation S510, the battery control apparatus according to an embodiment may perform preprocessing for diagnosing a battery.

In one embodiment, the performing of the preprocessing may include stopping using the battery during a specified time.

In one embodiment, the performing of the preprocessing may include determining whether a temperature of the battery is less than or equal to a specified temperature (e.g., about 10 degrees Celsius).

In another embodiment, the performing of the preprocessing may include determining whether a temperature deviation between battery cells is less than or equal to a specified temperature deviation (e.g., about 5 degrees).

Referring to FIG. 5, in an operation S520, the battery control apparatus according to an embodiment may charge or discharge the battery, based on identifying a diagnosis area.

For example, the battery control apparatus may perform at least one of charging or discharging, or any combination thereof of the battery in at least a portion of the diagnosis area to obtain battery data, based on a specified current.

Referring to FIG. 5, in an operation S530, the battery control apparatus according to an embodiment may perform first calculation for obtaining cell data corresponding to a sub-diagnosis area.

The battery control apparatus may compare the cell data with reference data, based on performing the first calculation.

Referring to FIG. 5, in an operation S540, the battery control apparatus according to an embodiment may perform second calculation for obtaining an abnormal state of the battery using the cell data.

For example, the battery control apparatus may compare the cell data with the reference data based on performing the second calculation to identify a battery cell diagnosed as being in the abnormal state.

Referring to FIG. 5, in an operation S550, the battery control apparatus according to an embodiment may identify a risk of the battery that is diagnosed as being in the abnormal state.

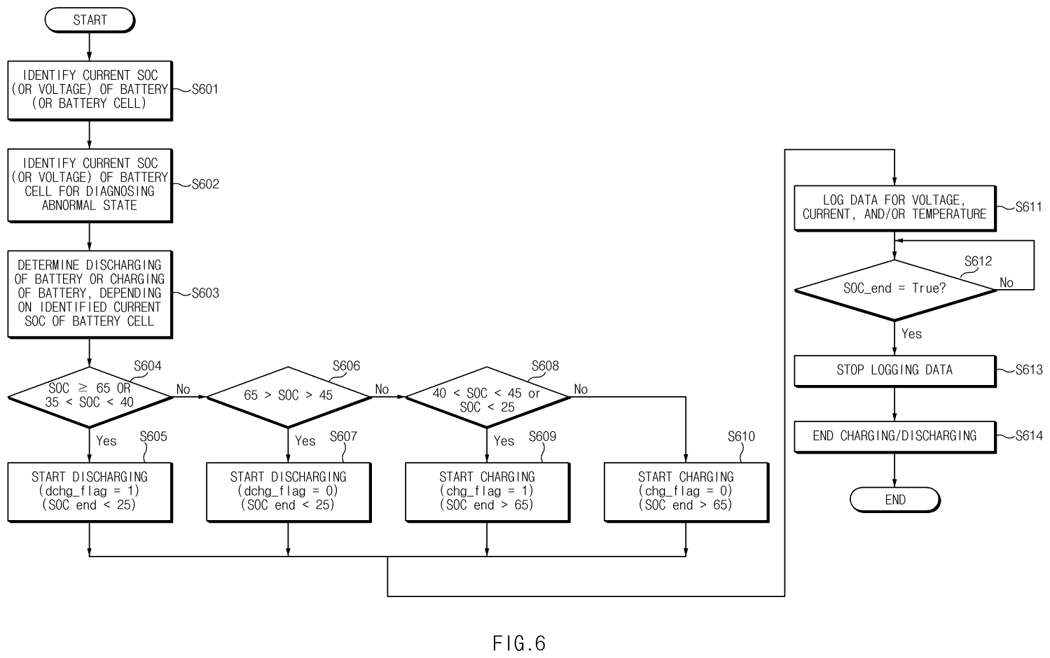

FIG. 6 illustrates a flowchart illustrating an operation of obtaining battery data in a battery control apparatus according to an embodiment of the present disclosure. Hereinafter, it is assumed that a battery control apparatus 100 of FIG. 1 performs a process of FIG. 6. Furthermore, in a description of FIG. 6, an operation described as being performed by a battery control apparatus may be understood as being controlled by a processor 110 of the battery control apparatus 100. The respective operations of FIG. 6 may be sequentially performed, but are not necessarily sequentially performed. For example, an order of the respective operations may be changed, and at least two operations may be performed in parallel. At least one of the operations of FIG. 6 may be associated with S520 of FIG. 5.

Referring to FIG. 6, in the operation S601, the battery control apparatus may identify a current SOC (or voltage) of a battery (or a battery cell).

Referring to FIG. 6, in the operation S602, the battery control apparatus according to an embodiment may identify a current SOC (or voltage) of the battery cell for diagnosing an abnormal state.

Referring to FIG. 6, in the operation S603, the battery control apparatus may determine discharging of the battery or charging of the battery, depending on the identified current SOC of the battery cell.

Referring to FIG. 6, in the operation S604, the battery control apparatus may identify whether the SOC of the battery is greater than or equal to 65% or the SOC of the battery is between 35% and 40%. For example, if the SOC of the battery is greater than or equal to 65% or the SOC of the battery is between 35% and 40% (i.e., Yes in the operation S604), the battery control apparatus may discharge the battery from the current SOC to 25% in the operation S605.

For example, the battery control apparatus may store data (e.g., dchg_flag=1) about performing the operation S605.

For example, the battery control apparatus may obtain battery data for all of a diagnosis area (e.g., a diagnosis area 310 of FIG. 3), based on performing the operation S605. For example, the battery control apparatus may obtain battery data for a second sub-diagnosis area (e.g., a second sub-diagnosis area 312 of FIG. 3), based on performing the operation S605.

Referring to FIG. 6, if the SOC of the battery is less than 65% or the SOC of the battery is not included between 35% and 40% (No in the operation S604), the battery control apparatus may identify whether the SOC of the battery is included between 45% and 65% in the operation S606. For example, if the SOC of the battery is included between 45% and 65% (Yes in the operation S606), the battery control apparatus may discharge the battery from the current SOC to 25% in the operation S607.

For example, the battery control apparatus may store data (e.g., dchg_flag=0) about performing the operation S607.

For example, the battery control apparatus may obtain battery data for a first sub-diagnosis area (e.g., a first sub-diagnosis area 311 of FIG. 3) and/or the second sub-diagnosis area (e.g., the second sub-diagnosis area 312 of FIG. 3), based on performing the operation S607.

Referring to FIG. 6, if the SOC of the battery is not included between 45% and 65% (No in the operation S606), the battery control apparatus may identify whether the SOC of the battery is included between 40% and 45% or the SOC of the battery is less than 25% in the operation S608. For example, if the SOC of the battery is included between 40% and 45% or the SOC of the battery is less than 25%, the battery control apparatus may charge the battery from the current SOC to 65% in the operation S609.

For example, the battery control apparatus may store data (e.g., chg_flag=1) about performing the operation S609.

For example, the battery control apparatus may obtain battery data for the first sub-diagnosis area (e.g., the first sub-diagnosis area 311 of FIG. 3) and/or battery data for all of the diagnosis area (e.g., the diagnosis area 310 of FIG. 3), based on performing S609.

For example, if the SOC of the battery is not included between 40% and 45% or the SOC of the battery is not less than 25% (i.e., No in the operation S608), the battery control apparatus may charge the battery from the current SOC to 65% in the operation S610.

For example, the battery control apparatus may store data (e.g., chg_flag=0) about performing the operation S610.

For example, the battery control apparatus may obtain battery data for the first sub-diagnosis area (e.g., the first sub-diagnosis area 311 of FIG. 3) and/or battery data for all of the second sub-diagnosis area (e.g., the second sub-diagnosis area 312 of FIG. 3), based on performing the operation S609.

Referring to FIG. 6, after performing at least one of the operations S605, S607, S609, or S610, the battery control apparatus may log the battery data (e.g., data for a voltage, a current, and/or a temperature) in the operation S611.

Referring to FIG. 6, in the operation S612, the battery control apparatus may check whether an error for the battery data is not identified. If the error for the battery data is identified (No in the operation S612), the battery control apparatus may temporarily refrain from performing the operation S613.

Referring to FIG. 6, if the error for the battery data is not identified (Yes in the operation S612, the battery control apparatus may stop logging the battery data (or log the battery data) in the operation S613.

Referring to FIG. 6, in the operation S614, the vehicle control device according to an embodiment may end the performance of the operation of charging or discharging the battery.

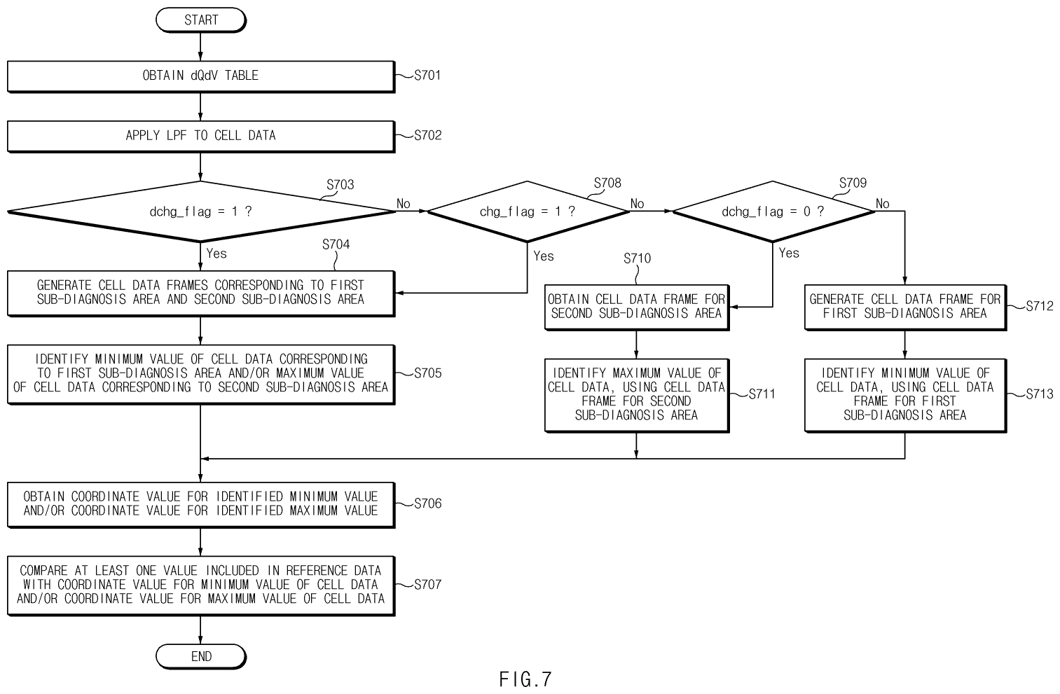

FIG. 7 illustrates a flowchart illustrating a preprocessing operation for comparing cell data with reference data in a battery control apparatus according to an embodiment of the present disclosure. Hereinafter, it is assumed that a battery control apparatus 100 of FIG. 1 performs a process of FIG. 7. Furthermore, in a description of FIG. 7, an operation described as being performed by a battery control apparatus may be understood as being controlled by a processor 110 of the battery control apparatus 100. The respective operations of FIG. 7 may be sequentially performed, but are not necessarily sequentially performed. For example, an order of the respective operations may be changed, and at least two operations may be performed in parallel. At least one of the operations of FIG. 7 may be associated with S530 of FIG. 5. At least one of the operations of FIG. 7 may be performed, after performing at least one of the operations of FIG. 6.

Referring to FIG. 7, in the operation S701, the battery control apparatus may obtain cell data (e.g., a dQdV table) (e.g., cell data 250 of FIG. 2), using battery data obtained by performing at least one of the operations of FIG. 6.

For example, in the operation S702, the battery control apparatus may apply a filter (e.g., a low pass filter (LPF)) for removing noise included in the cell data to the cell data, thus removing the noise.

The battery control apparatus may check whether the operation S605 is performed to obtain battery data. For example, the battery control apparatus may process data (e.g., dchg_flag=1) stored after performing the operation S605, thus checking whether the operation S605 is performed.

For example, if the operation S605 to obtain the battery data is not performed, the battery control apparatus may determine whether the operation S609 to obtain the battery data is performed in the operation S708. For example, the battery control apparatus may process data (e.g., dchg_flag=1) stored after performing the operation S609, thus checking whether the operation S609 is performed.

Referring to FIG. 7, if the operation S605 is performed (Yes in the operation S703) or if the operation S609 is performed to obtain the battery data (Yes in the operation S708), the battery control apparatus may generate cell data frames corresponding to a first sub-diagnosis area and a second sub-diagnosis area in the operation S704. The battery control apparatus may obtain the cell data frames corresponding to the first sub-diagnosis area and the second sub-diagnosis area from all cell data to reduce an amount of calculation of an operation for diagnosing a battery. However, it is not limited thereto.

Referring to FIG. 7, in the operation S705, the battery control apparatus may identify a minimum value of cell data corresponding to the first sub-diagnosis area and/or a maximum value of cell data corresponding to the second sub-diagnosis area.

For example, the minimum value of the cell data corresponding to the first sub-diagnosis area may be included in a first inflection point area 410 of FIG. 4.

For example, the maximum value of the cell data corresponding to the second sub-diagnosis area may be included in a second inflection point area 420 of FIG. 4.

Referring to FIG. 7, in the operation S706, the battery control apparatus may obtain a coordinate value for the identified minimum value of the cell data corresponding to the first sub-diagnosis area and/or a coordinate value (e.g., an x-coordinate value and a y-coordinate value) for the identified maximum value of the cell data corresponding to the second sub-diagnosis area.

Referring to FIG. 7, in the operation S707, the battery control apparatus may compare at least one value included in reference data with the coordinate value for the minimum value of the cell data corresponding to the first sub-diagnosis area and/or the coordinate value for the maximum value of the cell data corresponding to the second sub-diagnosis area.

Referring to FIG. 7, if the operation S609 is not performed (No in the operation S708), the battery control apparatus may determine whether the operation S607 is performed to obtain battery data. For example, the battery control apparatus may process data (e.g., dchg_flag=0) stored after performing the operation S607, thus checking whether the operation S607 is performed.

Referring to FIG. 7, if the operation S607 is performed to obtain the battery data (Yes in the operation S709), the battery control apparatus may obtain a cell data frame for the second sub-diagnosis area in the operation S710.

Referring to FIG. 7, in the operation S711, the battery control apparatus according to an embodiment may identify the maximum value of the cell data, using the cell data frame for the second sub-diagnosis area. For example, in the operation S706, the battery control apparatus may store a coordinate value for the maximum value of the cell data included in the second sub-diagnosis area. For example, in the operation S707, the battery control apparatus may calculate a distance between the coordinate value for the maximum value and at least one value (e.g., an inflection point) of the reference data.

Referring to FIG. 7, if the operation S607 to obtain the battery data is performed (Yes in the operation S709), the battery control apparatus may obtain the cell data frame for the second sub-diagnosis area in the operation S710.

Referring to FIG. 7, if the operation S607 to obtain the battery data is not performed (No in the operation S709), the battery control apparatus may generate a cell data frame for the first sub-diagnosis area in the operation S712.

Referring to FIG. 7, in the operation S713, the battery control apparatus according to an embodiment may identify the minimum value of the cell data, using the cell data frame for the first sub-diagnosis area. For example, in the operation S706, the battery control apparatus may store the coordinate value for the minimum value. For example, in the operation S707, the battery control apparatus may calculate the distance between the coordinate value and the at least one value of the reference data.

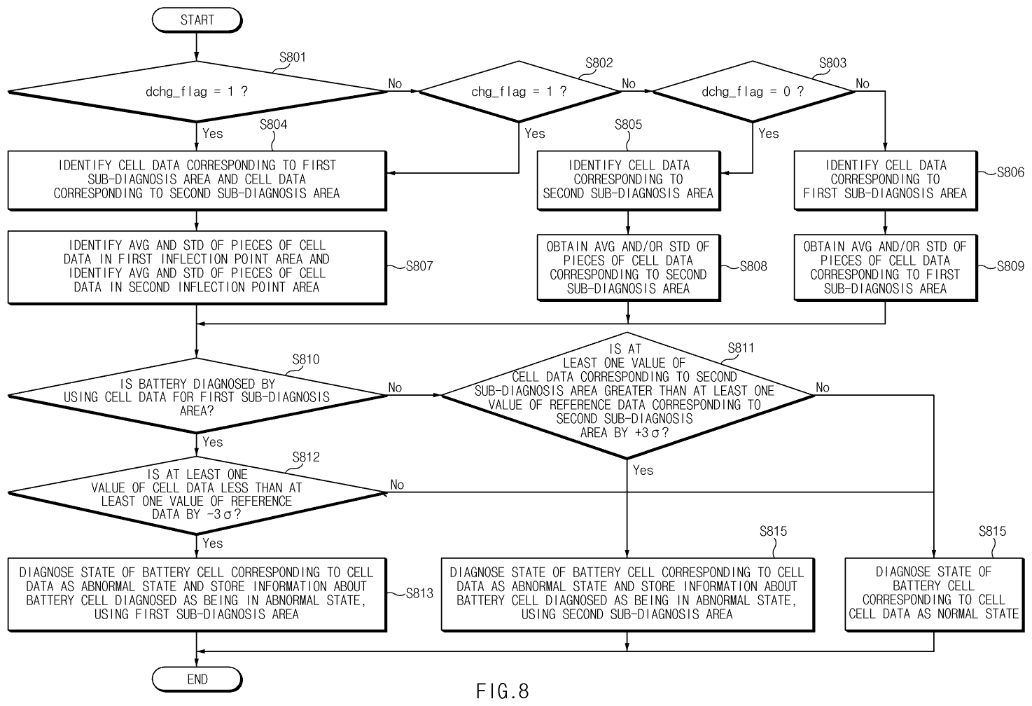

FIG. 8 illustrates of a flowchart illustrating an operation of diagnosing a battery cell using cell data in a battery control apparatus according to an embodiment of the present disclosure. Hereinafter, it is assumed that a battery control apparatus 100 of FIG. 1 performs a process of FIG. 8. Furthermore, in a description of FIG. 8, an operation described as being performed by a battery control apparatus may be understood as being controlled by a processor 110 of the battery control apparatus 100. The respective operations of FIG. 8 may be sequentially performed, but are not necessarily sequentially performed. For example, an order of the respective operations may be changed, and at least two operations may be performed in parallel. At least one of the operations of FIG. 8 may be associated with the operation S540 of FIG. 5. At least one of the operations of FIG. 8 may be performed, after at least one of the operations of FIG. 7 is performed.

Referring to FIG. 8, in the operation S801, the battery control apparatus may perform the operation S605 of FIG. 6 to check whether battery data is obtained.

if the operation S605 of FIG. 6 to obtain the battery data is not performed (No in the operation S801), the battery control apparatus may determine whether the operation S609 of FIG. 6 to obtain the battery data is performed in the operation S802.

Referring to FIG. 8, if the operation S605 of FIG. 6 to obtain the battery data is performed (Yes in the operation S801) or if the operation S609 of FIG. 6 to obtain the battery data is performed (Yes in the operation S802, the battery control apparatus may identify cell data corresponding to a first sub-diagnosis area and cell data corresponding to a second sub-diagnosis area in the operation S804.

For example, the battery control apparatus may obtain cell data for each of a plurality of battery cells.

Referring to FIG. 8, in the operation S807, the battery control apparatus may identify an average value AVG and a specified value (e.g., a standard deviation STD) of the pieces of cell data in a first inflection point area (e.g., a first inflection point area 410 of FIG. 4), using the cell data corresponding to the first sub-diagnosis area and the cell data corresponding to the second sub-diagnosis area. For example, the battery control apparatus may identify an average value AVG and a specified value (e.g., a standard deviation STD) of the pieces of cell data in a second inflection point area (e.g., a second inflection point area 420 of FIG. 4), using the cell data corresponding to the first sub-diagnosis area and the cell data corresponding to the second sub-diagnosis area.

Referring to FIG. 8, if the operation S609 of FIG. 6 to obtain the battery data is not performed (No in the operation S802), the battery control apparatus may check whether the operation S607 of FIG. 6 to obtain the battery data is performed in the operation S803.

Referring to FIG. 8, if the operation S607 to obtain the battery data is performed (Yes in the operation S803), the battery control apparatus may identify the cell data corresponding to the second sub-diagnosis area in the operation S805. For example, in S808, the battery control apparatus may obtain an average value AVG and/or a specified value (e.g., a standard deviation STD) of pieces of cell data corresponding to the second sub-diagnosis area.

Referring to FIG. 8, if the operation S607 to obtain the battery data is not performed (No in the operation S803), the battery control apparatus may identify the cell data corresponding to the first sub-diagnosis area in the operation s806. For example, in the operation S809, the battery control apparatus may obtain an average value AVG and/or a specified value (e.g., a standard deviation STD) of pieces of cell data corresponding to the first sub-diagnosis area.

Referring to FIG. 8, in the operation S810, the battery control apparatus may determine whether a battery is diagnosed by using the cell data for the first sub-diagnosis area. Hereinafter, the cell data used to perform the operations S810 to S815 by the battery control apparatus may vary according to whether obtained after any of the operations S807 to S809 is performed by the battery control apparatus. However, it is not limited thereto.

Referring to FIG. 8, if the battery is diagnosed by using the cell data for the first sub-diagnosis area (Yes in the operation S810), the battery control apparatus may identify whether at least one value of the cell data corresponding to the first sub-diagnosis area is less than at least one value of reference data corresponding to the first sub-diagnosis area by a specified value (e.g., −3 sigma).

For example, if the at least one value of the cell data is less than the at least one value of the reference data by the specified value (e.g., −3 sigma) (Yes in the operation S812—Yes), the battery control apparatus may diagnose a state of a battery cell corresponding to the cell data as an abnormal state in the operation S813.

For example, the battery control apparatus may store information about the battery cell diagnosed as being in the abnormal state, using the first sub-diagnosis area.

For example, if the at least one value of the cell data is not less than the at least one value of the reference data by the specified value (e.g., −3 sigma) (No in the operation S812), the battery control apparatus may diagnose the state of the battery cell corresponding to the cell data as a normal state in the operation S815. For example, in the operation S815, the battery control apparatus may identify that there is no battery cell diagnosed as being in the abnormal state.

Referring to FIG. 8, if the battery is diagnosed without using the cell data for the first sub-diagnosis area (No in the operation S810), the battery control apparatus may identify, in the operation S811, whether at least one value of the cell data corresponding to the second sub-diagnosis area is greater than at least one value of reference data corresponding to the second sub-diagnosis area by a specified value (e.g., +3 sigma).

For example, if the at least one value of the cell data is greater than the at least one value of the reference data by the specified value (e.g., +3 sigma) (Yes in the operation S811), the battery control apparatus may diagnose the state of the battery cell corresponding to the cell data as the abnormal state in the operation S814.

For example, the battery control apparatus may store information about the battery cell diagnosed as being in the abnormal state, using the second sub-diagnosis area.

For example, if the at least one value of the cell data is not greater than the at least one value of the reference data by the specified value (e.g., +3 sigma) (No in the operation S811), the battery control apparatus may diagnose the state of the battery cell corresponding to the cell data as the normal state in the operation S815.

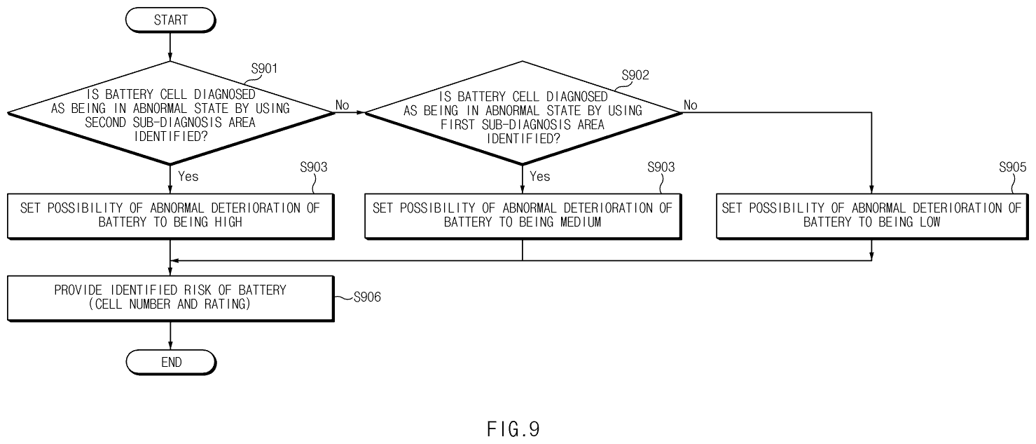

FIG. 9 illustrates an example of an operation of determining a risk of a diagnosed battery cell in a battery control apparatus according to an embodiment of the present disclosure. Hereinafter, it is assumed that a battery control apparatus 100 of FIG. 1 performs a process of FIG. 9. Furthermore, in a description of FIG. 9, an operation described as being performed by a battery control apparatus may be understood as being controlled by a processor 110 of the battery control apparatus 100. The respective operations of FIG. 9 may be sequentially performed, but are not necessarily sequentially performed. For example, an order of the respective operations may be changed, and at least two operations may be performed in parallel. At least one of the operations of FIG. 9 may be associated with S550 of FIG. 5. At least one of the operations of FIG. 9 may be performed, after at least one of the operations of FIG. 8 is performed.

Referring to FIG. 9, in the operation S901, the battery control apparatus according to an embodiment may check whether a battery cell diagnosed as being in an abnormal state is identified using a second sub-diagnosis area.

For example, if performing the operation S811 of FIG. 8, the battery control apparatus may identify the battery cell diagnosed as being in the abnormal state using the second sub-diagnosis area.

For example, if the battery cell diagnosed as being in the abnormal state by using the second sub-diagnosis area is identified (Yes in the operation S901), the battery control apparatus may set a risk (e.g., a possibility of abnormal deterioration) of the battery to a first risk (e.g., being high) in the operation S903.

For example, if the battery cell diagnosed as being in the abnormal state by using the second sub-diagnosis area is not identified (No in the operation S901), the battery control apparatus may check whether the battery cell diagnosed as being in the abnormal state is identified using a first sub-diagnosis area in the operation S902.

For example, if the operation S813 of FIG. 8 is performed, the battery control apparatus may identify the battery cell diagnosed as being in the abnormal state using the first sub-diagnosis area.

For example, if the battery cell diagnosed as being in the abnormal state using the first sub-diagnosis area is identified (Yes in the operation S902), the battery control apparatus may set the risk (e.g., the possibility of abnormal deterioration) of the battery to a second risk (e.g., being medium) in the operation S904.

For example, if the battery cell diagnosed as being in the abnormal state using the first sub-diagnosis area is not identified (S902—No), the battery control apparatus may set the risk (e.g., the possibility of abnormal deterioration) of the battery to a third risk (e.g., being low) in the operation S905.

Referring to FIG. 9, in the operation S906, the battery control apparatus may perform the operation(s) S903, S904, and/or S905 to provide the identified risk of the battery. The risk of the battery may include identification information of the battery cell. The risk of the battery may include a diagnosed result.

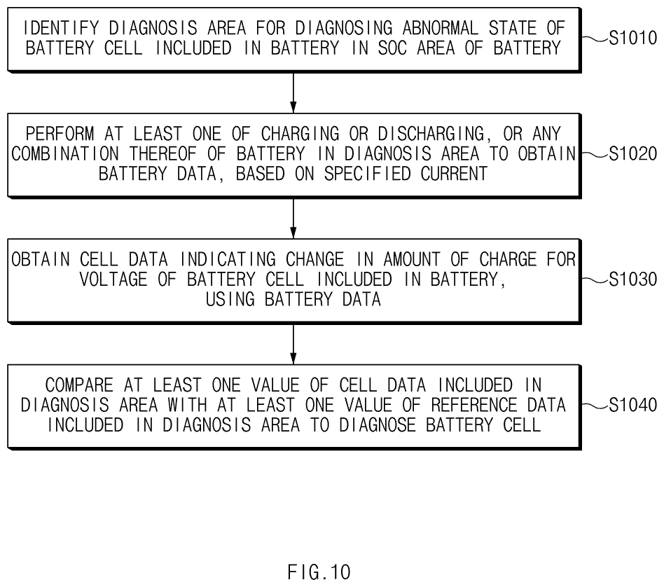

FIG. 10 illustrates an example of a flowchart illustrating an operation of a battery control apparatus according to an embodiment of the present disclosure. Hereinafter, it is assumed that a battery control apparatus 100 of FIG. 1 performs a process of FIG. 10. Furthermore, in a description of FIG. 10, an operation described as being performed by a battery control apparatus may be understood as being controlled by a processor 110 of the battery control apparatus 100. The respective operations of FIG. 10 may be sequentially performed, but are not necessarily sequentially performed. For example, an order of the respective operations may be changed, and at least two operations may be performed in parallel. At least one of the operations of FIG. 10 may be associated with at least one of the operations of FIG. 5.

Referring to FIG. 10, in the operation S1010, the battery control apparatus may identify a diagnosis area for diagnosing an abnormal state of a battery cell included in a battery in an SOC area of the battery.

For example, the battery control apparatus may identify a current SOC of a vehicle to identify the diagnosis area including at least one of a first sub-diagnosis area or a second sub-diagnosis area, or any combination thereof.

Referring to FIG. 10, in the operation S1020, the battery control apparatus may perform at least one of charging or discharging, or any combination thereof of the battery in the diagnosis area to obtain battery data, based on a specified current. For example, the operation S1010 and/or the operation S1020 may be the associated with as S520 of FIG. 5.

Referring to FIG. 10, in the operation S1030, the battery control apparatus may obtain cell data indicating a change in amount of charge for the voltage of the battery cell included in the battery, using the battery data. For example, the operation S1030 may be associated with the operation S530 of FIG. 5.

Referring to FIG. 10, in the operation S1040, the battery control apparatus may compare at least one value of the cell data included in the diagnosis area with at least one value of reference data included in the diagnosis area to diagnose the battery cell. S1040 may be associated with the operation S540 of FIG. 5.

For example, if diagnosing the state of the battery cell as the abnormal state, the battery control apparatus may identify a risk of the battery cell diagnosed as being in the abnormal state. The battery control apparatus may provide information indicating the risk.

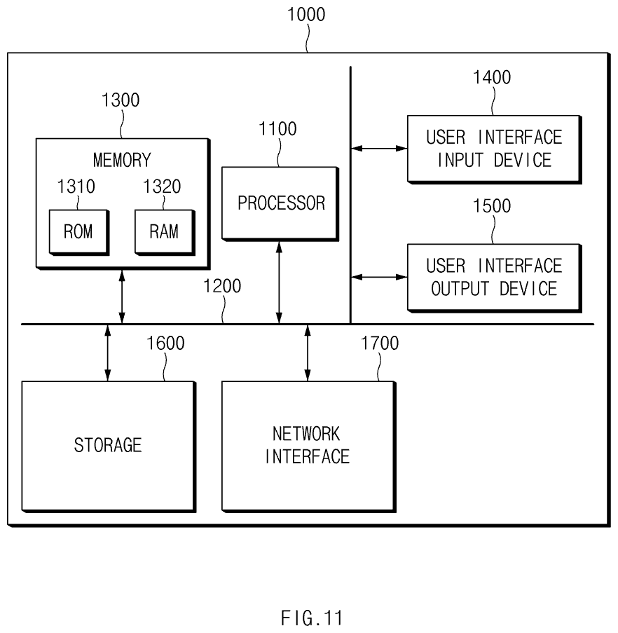

FIG. 11 illustrates a computing system associated with a battery control apparatus or a battery control method according to an embodiment of the present disclosure.

Referring to FIG. 11, The computing system 1000 may include at least one processor 1100, a memory 1300, a user interface input device 1400, a user interface output device 1500, storage 1600, and a network interface 1700 connected through a system bus 1200.

The processor 1100 may be a central processing device (CPU) or a semiconductor device that processes instructions stored in the memory 1300 and/or the storage 1600.

The memory 1300 and the storage 1600 may include various types of volatile or non-volatile storage media. For example, the memory 1300 may include a ROM (Read Only Memory) 1310 and a RAM (Random Access Memory) 1320.

Thus, the operations of the method or the algorithm described in connection with the embodiments disclosed herein may be embodied directly in hardware or a software module executed by the processor 1100, or in a combination thereof. The software module may reside on a storage medium (i.e., the memory 1300 and/or the storage 1600) such as a RAM, a flash memory, a ROM, an EPROM, an EEPROM, a register, a hard disk, a removable disk, and a CD-ROM.

The storage medium may be coupled to the processor 1100, and the processor 1100 may read information out of the storage medium and may record information in the storage medium. Alternatively, the storage medium may be integrated with the processor 1100. The processor 1100 and the storage medium may reside in an application specific integrated circuit (ASIC). The ASIC may reside within a user terminal. In another case, the processor 1100 and the storage medium may reside in the user terminal as separate components.

The present technology may diagnose the state of the battery.

The present technology may set a diagnosis area with a high frequency of use in an SOC area of the battery.

Furthermore, the present technology may provide a risk of the battery diagnosed as being in an abnormal state.

In addition, various effects ascertained directly or indirectly through the present disclosure may be provided.

Hereinabove, although the present disclosure has been described with reference to embodiments and the accompanying drawings, the present disclosure is not limited thereto, but may be variously modified and altered by those having ordinary skill in the art to which the present disclosure pertains without departing from the spirit and scope of the present disclosure claimed in the following claims.

Therefore, embodiments of the present disclosure are not intended to limit the technical spirit of the present disclosure, but provided only for the illustrative purpose. The scope of the present disclosure should be construed on the basis of the accompanying claims, and all the technical ideas within the scope equivalent to the claims should be included in the scope of the present disclosure.

What is claimed is:

1. A battery control apparatus, comprising:
a battery;
a processor; and
a memory configured to store one or more instructions executable by the processor,
wherein the processor is configured to:
identify a diagnosis area within a state of charge (SOC) area of the battery, wherein the diagnosis area is for diagnosing an abnormal state of a battery cell included in the battery;
perform at least one of charging, discharging, or any combination thereof of the battery in the diagnosis area to obtain battery data, based on a specified current;
obtain cell data indicating a change in amount of charge for a voltage of the battery cell included in the battery, using the battery data; and
compare at least one value of the cell data corresponding to the diagnosis area with at least one value of reference data corresponding to the diagnosis area to diagnose the battery cell.

2. The battery control apparatus of claim 1, wherein the diagnosis area includes a first sub-diagnosis area and a second sub-diagnosis area, the second sub-diagnosis area including a SOC value smaller than at least one SOC value included in the first sub-diagnosis area, and
wherein the processor is configured to:
diagnose a state of the battery cell as the abnormal state when the at least one value of the cell data corresponding to at least one of the first sub-diagnosis area, the second sub-diagnosis area, or any combination thereof deviates from a diagnostic range including the at least one value of the reference data corresponding to at least one of the first sub-diagnosis area, the second sub-diagnosis area, or any combination thereof.

3. The battery control apparatus of claim 2, wherein the processor is configured to:
compare a minimum value of the cell data corresponding to the first sub-diagnosis area of the diagnosis area with a minimum value of the reference data corresponding to the first sub-diagnosis area; and
diagnose the state of the battery cell as the abnormal state when the minimum value of the cell data is less than the minimum value of the reference data by a specified value.

4. The battery control apparatus of claim 2, wherein the processor is configured to:
compare a maximum value of the cell data corresponding to the second sub-diagnosis area of the diagnosis area with a maximum value of the reference data corresponding to the second sub-diagnosis area; and
diagnose the state of the battery cell as the abnormal state, when the maximum value of the cell data is greater than the maximum value of the reference data by a specified value.

5. The battery control apparatus of claim 2, wherein the processor is configured to:
determine a risk of the battery cell diagnosed as being in the abnormal state, and
wherein the risk of the battery cell diagnosed as being in the abnormal state based on the first sub-diagnosis area includes a value smaller than another risk of the battery cell diagnosed as being in the abnormal state based on the second sub-diagnosis area.

6. The battery control apparatus of claim 1, wherein the diagnosis area has a higher frequency of use than another area differentiating from the diagnosis area in the SOC area of the battery.

7. The battery control apparatus of claim 6, wherein the processor is configured to:
compare the at least one value of the cell data corresponding to the diagnosis area with the at least one value of the reference data corresponding to the diagnosis area to diagnose the abnormal state of the battery cell, the abnormal state occurring in the another area differentiating from the diagnosis area in the SOC area of the battery.

8. The battery control apparatus of claim 1, wherein the processor is configured to:
identify an SOC of the battery; and
perform at least one of charging, discharging, or any combination thereof of the battery, based on the specified current, to obtain the battery data for at least a portion of the diagnosis area, based on identifying the SOC of the battery.

9. The battery control apparatus of claim 8, wherein the processor is configured to:
determine the at least a portion of the diagnosis area, wherein the at least a portion of the diagnosis area is adjacent to the SOC of the battery, based on identifying the SOC of the battery.

10. The battery control apparatus of claim 1, wherein the processor is configured to:
obtain the battery data, based on the specified current less than a threshold current.

11. A battery control method, comprising:
identifying a diagnosis area within a state of charge (SOC) area of a battery, wherein the diagnosis area is for diagnosing an abnormal state of a battery cell included in a battery;
performing at least one of charging, discharging, or any combination thereof of the battery in the diagnosis area to obtain battery data, based on a specified current;
obtaining the battery data;
obtaining cell data indicating a change in amount of charge for a voltage of the battery cell included in the battery, using the battery data;
comparing at least one value of the cell data corresponding to the diagnosis area with at least one value of reference data corresponding to the diagnosis area to diagnose the battery cell; and
diagnosing the battery cell.

12. The battery control method of claim 11, wherein the diagnosis area includes a first sub-diagnosis area and a second sub-diagnosis area, the second sub-diagnosis area including a SOC value smaller than at least one SOC value included in the first sub-diagnosis area, and
wherein diagnosing the battery cell includes:
diagnosing a state of the battery cell as the abnormal state when the at least one value of the cell data corresponding to at least one of the first sub-diagnosis area, the second sub-diagnosis area, or any combination thereof deviates from a diagnostic range including the at least one value of the reference data corresponding to at least one of the first sub-diagnosis area, the second sub-diagnosis area, or any combination thereof.

13. The battery control method of claim 12, wherein diagnosing the battery cell includes:
comparing a minimum value of the cell data corresponding to the first sub-diagnosis area of the diagnosis area with a minimum value of the reference data corresponding to the first sub-diagnosis area; and
diagnosing the state of the battery cell as the abnormal state when the minimum value of the cell data is less than the minimum value of the reference data by a specified value.

14. The battery control method of claim 12, wherein diagnosing the battery cell includes:
comparing a maximum value of the cell data corresponding to the second sub-diagnosis area of the diagnosis area with a maximum value of the reference data corresponding to the second sub-diagnosis area; and
diagnosing the state of the battery cell as the abnormal state when the maximum value of the cell data is greater than the maximum value of the reference data by a specified value.

15. The battery control method of claim 12, wherein diagnosing the battery cell includes:
determining a risk of the battery cell diagnosed as being in the abnormal state, and
wherein the risk of the battery cell diagnosed as being in the abnormal state based on the first sub-diagnosis area includes a value smaller than another risk of the battery cell diagnosed as being in the abnormal state based on the second sub-diagnosis area.

16. The battery control method of claim 11, wherein the diagnosis area has a higher frequency of use than another area differentiating from the diagnosis area in the SOC area of the battery.

17. The battery control method of claim 16, wherein diagnosing the battery cell includes:
comparing the at least one value of the cell data corresponding to the diagnosis area with the at least one value of the reference data corresponding to the diagnosis area to diagnose the abnormal state of the battery cell, the abnormal state occurring in the another area differentiating from the diagnosis area in the SOC area of the battery.

18. The battery control method of claim 11, wherein obtaining the battery data includes:
identifying an SOC of the battery; and
performing at least one of charging, discharging, or any combination thereof of the battery, based on the specified current, to obtain the battery data for at least a portion of the diagnosis area, based on identifying the SOC of the battery.

19. The battery control method of claim 18, wherein identifying the SOC of the battery includes:
determining the at least a portion of the diagnosis area, wherein the at least a portion of the diagnosis area is adjacent to the SOC of the battery, based on identifying the SOC of the battery.

20. The battery control method of claim 11, wherein obtaining the battery data includes:
obtaining the battery data, based on the specified current less than a threshold current.
